(19) United States
(12) Patent Application Publication
(10) Pub. No.: US 2015/0255296 A1
(43) Pub. Date: Sep. 10, 2015

(54) MANUFACTURING METHOD OF SEMICONDUCTOR DEVICE AND PHOTOMASK

(71) Applicant: Kabushiki Kaisha Toshiba, Minato-ku (JP)

(72) Inventors: Kazunori IIDA, Yokkaichi-shi (JP); Yuji Kobayashi, Yokkaichi-shi (JP)

(73) Assignee: Kabushiki Kaisha Toshiba, Minato-ku (JP)

(21) Appl. No.: 14/288,555

(22) Filed: May 28, 2014

Related U.S. Application Data
(60) Provisional application No. 61/950,616, filed on Mar. 10, 2014.

(51) Int. Cl. H01L 21/302; G03F 1/42; H01L 21/027

(52) U.S. Cl. CPC H01L 21/302; H01L 21/0274; G03F 1/42

(57) ABSTRACT

According to one embodiment, a photomask includes first lines and spaces that have a longitudinal side set along a first direction and are arranged in an effective region, and second lines and spaces that have a longitudinal side set along a second direction different from the first direction and are arranged in a peripheral region.

### CROSS-REFERENCE TO RELATED APPLICATIONS

This application is based upon and claims the benefit of priority from Provisional Patent Application No. 61/950,616, filed on Mar. 10, 2014; the entire contents of which are incorporated herein by reference.

### FIELD

Embodiments described herein relate generally to a manufacturing method of a semiconductor device, and a photomask.

### BACKGROUND

In a process for manufacturing a semiconductor device, reference marks are formed on a wafer to align an upper-layer pattern on an upper layer and a lower-layer pattern on a lower layer, or measure position gaps therebetween.

### BRIEF DESCRIPTION OF THE DRAWINGS

FIG. 1A is a plane view of a configuration example of a photomask on a lower layer according to a first embodiment, and FIGS. 1B to 1D are plane views of configuration examples of a photomask on an upper layer according to the first embodiment;

FIGS. 2A, 3A, 4A, 5A, 6A, and 7A are plane views illustrating manufacturing methods of a semiconductor device in a peripheral region according to a second embodiment, FIGS. 2B, 3B, 4B, 5B, 6B, and 7B are cross-sectional views of FIGS. 2A, 3A, 4A, 5A, 6A, and 7A taken along line B-B, respectively, FIGS. 2C, 3C, 4C, 5C, 6C, and 7C are plane views illustrating manufacturing methods of a semiconductor device in an effective region according to the second embodiment, and FIGS. 2D, 3D, 4D, 5D, 6D, and 7D are cross-sectional views of FIGS. 2C, 3C, 4C, 5C, 6C, and 7C taken along line A-A, respectively;

FIG. 8A is a plane view illustrating the observed state of overlapping gap measurement marks in the case where lines and spaces on the lower layer in the peripheral region are equally inclined in the peripheral region and the effective region, and FIG. 8B is a plane view illustrating the observed state of the overlapping gap measurement marks in the case where lines and spaces on the lower layer in the peripheral region are differently inclined in the peripheral region and the effective region; and

FIG. 9 is a schematic perspective view of a semiconductor device to which a photomask according to a third embodiment is applied.

### DETAILED DESCRIPTION

In general, according to one embodiment, a photomask includes first lines and spaces arranged in an effective region with a longitudinal side along a first direction, and second lines and spaces arranged in a peripheral region with a longitudinal side along a second direction different from the first direction.

Exemplary embodiments of a manufacturing method of a semiconductor and a photomask will be explained below in detail with reference to the accompanying drawings. The present invention is not limited to the following embodiments.

### First Embodiment

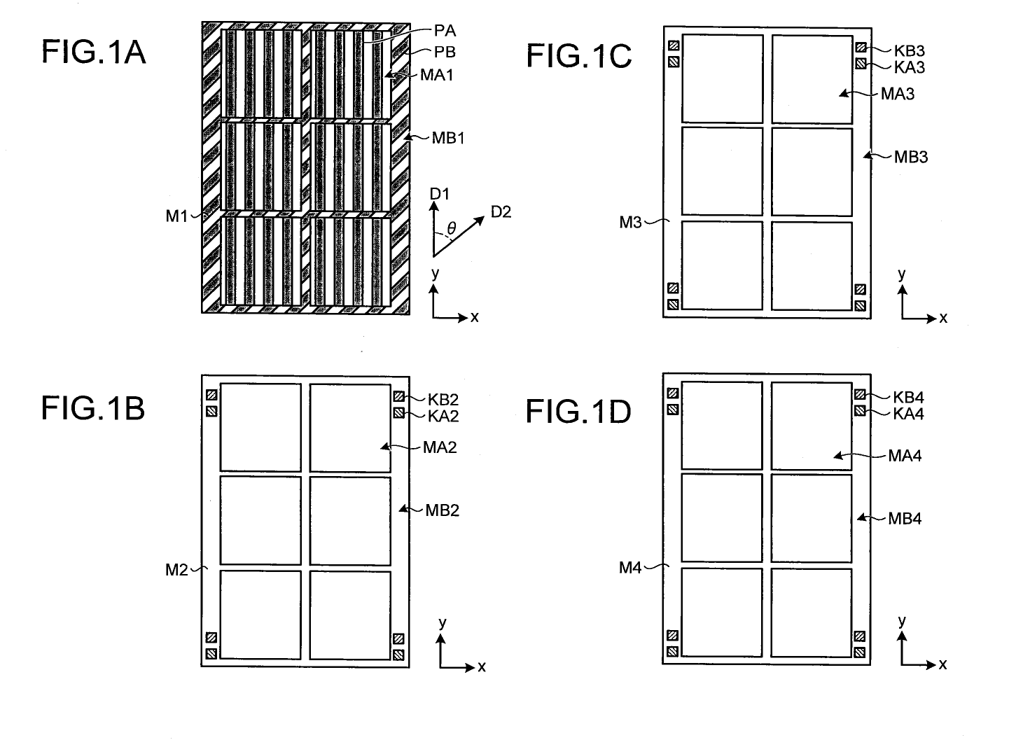

FIG. 1A is a plane view of a configuration example of a photomask on a lower layer according to a first embodiment, and FIGS. 1B to 1D are plane views of configuration examples of a photomask on an upper layer according to the first embodiment.

Referring to FIG. 1A, a photomask M1 is provided with an effective region MA1 and a peripheral region MB1. A mask pattern to be a constitutional element of a device may be formed in the effective region MA1. The mask pattern formed in the effective region MA1 is incorporated into the device. Reference marks such as alignment marks and overlapping gap measurement marks may be formed in the peripheral region MB1. The peripheral region MB1 may be a kerf region. A mask pattern not to be a constitutional element of the device may be formed in the peripheral region MB1. The mask pattern formed in the peripheral region MB1 is referred to at manufacture of the device but is not incorporated into the device. The device may be a device having a cyclic pattern to be a constitutional element, such as an NAND-type flash memory, for example. The constitutional element of the device may be bit lines, word lines, active regions, and the like of an NAND-type flash memory, for example.

Lines and spaces PA are arranged in the effective region MA1, and lines and spaces PB are arranged in the peripheral region MB1. The longitudinal side of the lines and spaces PA is set along a first direction D1, and the longitudinal side of the lines and spaces PB is set along a second direction D2 different from the first direction D1. An inclination angle θ of the second direction D2 with respect to the first direction D1 may be set within the range of 20 to 80 degrees. The lines and spaces PA and PB may be equal in pitch. The first direction D1 may be equalized to an x-axis or y-axis direction.

Referring to FIG. 1B, a photomask M2 is provided with an effective region MA2 and a peripheral region MB2. Alignment marks KB2 and overlapping gap measurement marks KA2 are arranged in the peripheral region MB2.

Referring to FIG. 1C, a photomask M3 is provided with an effective region MA3 and a peripheral region MB3. Alignment marks KB3 and overlapping gap measurement marks KA3 are arranged in the peripheral region MB3.

Referring to FIG. 1D, a photomask M4 is provided with an effective region MA4 and a peripheral region MB4. Alignment marks KB4 and overlapping gap measurement marks KA4 are arranged in the peripheral region MB4.

The alignment marks KB2 to KB4 may be used in position adjustment of the photomasks M1 to M4 and the patterns on the wafer on exposure. The overlapping gap measurement marks KA2 to KA4 may be used in measurement of an overlapping gap between the lower pattern and the upper pattern on the wafer. On the alignment and overlapping gap measurement, visible light or light in a longer-wavelength region may be used. Incidentally, the alignment marks KB2 to KB4 and the overlapping gap measurement marks KA2 to KA4 may be of box-in-box type, bar-in-bar type, line-and-space type, or the like, for example. In addition, the alignment marks KB2 to KB4 and the overlapping gap measurement marks KA2 to KA4 may be adjusted in mark dimensions, density, and coverage or may be selected as convex marks, concave marks, or segment marks, or the like, to provide sufficient margins for exposure conditions for device patterns (exposure amount and focus). The alignment marks KB2 to KB4 and the overlapping gap measurement marks KA2 to KA4 may overlap on the lines and spaces PB. In addition, edges of the alignment marks KB2 to KB4 and the overlapping gap measurement marks KA2 to KA4 may be set along a direction different from the second direction D2. For example, the edges of the alignment marks KB2 to KB4 and the overlapping gap measurement marks KA2 to KA4 may be set along the first direction D1. In addition, the edges of the alignment marks KB2 to KB4 and the overlapping gap measurement marks KA2 to KA4 may be set along the x-axis or y-axis direction. In addition, the alignment on exposure and the overlapping gap measurement after the exposure are performed in the x and y directions, and, for example, are performed in a direction parallel to and perpendicular to the longitudinal side of the lines and spaces PA in the effective region MA1.

By arranging the lines and spaces PA and PB in the effective region MA1 and the peripheral region MB1 of the photomask M1, respectively, it is possible to make foundation structures of process patterns corresponding to the alignment marks KB2 to KB4 and the overlapping gap measurement marks KA2 to KA4 equivalent to a process pattern corresponding to the lines and spaces PA. Accordingly, in the case where process conditions are optimized for the process pattern corresponding to the lines and spaces PA, process conditions can also be optimized for the foundation structure including the process patterns corresponding to the alignment marks KB2 to KB4 and the overlapping gap measurement marks KA2 to KA4. This makes it possible to improve the dimension accuracy of the process patterns corresponding to the alignment marks KB2 to KB4 and the overlapping gap measurement marks KA2 to KA4.

In addition, by setting differently the longitudinal sides of the lines and spaces PA and PB, it is possible to prevent that the edges of the process patterns corresponding to the alignment marks KB2 to KB4 and the overlapping gap measurement marks KA2 to KA4 cannot be differentiated from the edges of the process patterns of the foundation structures. This makes it possible to reduce errors in the alignment on exposure or the overlapping gap measurement after the exposure.

### Second Embodiment

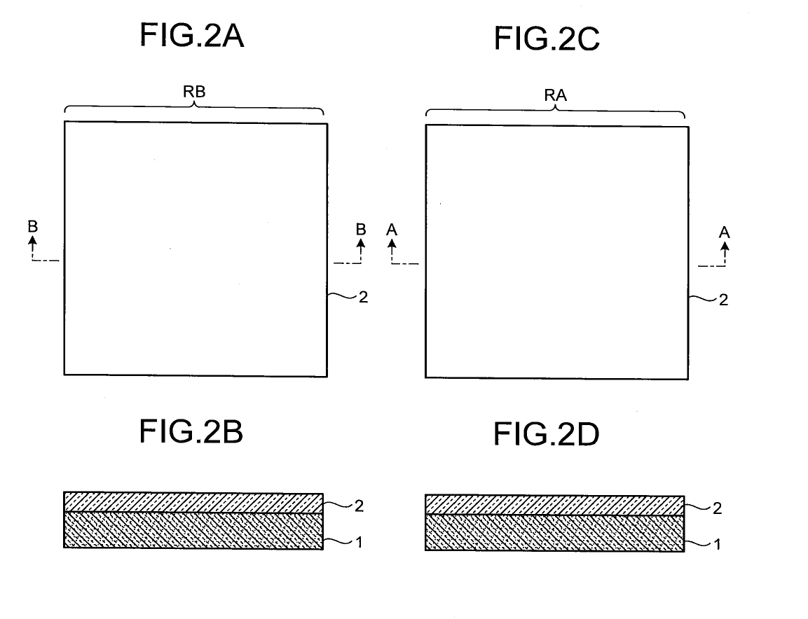

FIGS. 2A, 3A, 4A, 5A, 6A, and 7A are plane views illustrating manufacturing methods of a semiconductor device in a peripheral region according to a second embodiment, FIGS. 2B, 3B, 4B, 5B, 6B, and 7B are cross-sectional views of FIGS. 2A, 3A, 4A, 5A, 6A, and 7A taken along line B-B, respectively, FIGS. 2C, 3C, 4C, 5C, 6C, and 7C are plane views illustrating manufacturing methods of a semiconductor device in an effective region according to the second embodiment, and FIGS. 2D, 3D, 4D, 5D, 6D, and 7D are cross-sectional views of FIGS. 2C, 3C, 4C, 5C, 6C, and 7C taken along line A-A, respectively.

Referring to FIGS. 2A to 2D, a semiconductor substrate 1 is provided with an effective region RA and a peripheral region RB. In the effective region RA, a mask pattern in the effective region MA1 on the photomask M1 may be transferred to a lower layer, and a mask pattern in the effective region MA2 on the photomask M2 may be transferred to an upper layer. In the peripheral region RB, a mask pattern in the peripheral region MB1 on the photomask M1 may be transferred to the lower layer, and a mask pattern in the peripheral region MB2 on the photomask M2 may be transferred to the upper layer.

In addition, as illustrated in FIGS. 2A to 2D, a hard mask material 2 is formed in the effective region RA and the peripheral region RB of the semiconductor substrate 1, by a method such as CVD, for example. The material for the semiconductor substrate 1 may be Si, Ge, SiGe, SiC, SiSn, PbS, GaAs, InP, InGaAsP, GaP, GaN, ZnSe, or the like, for example. The material for the hard mask material 2 may be a silicon dioxide film or a silicon nitride film, for example.

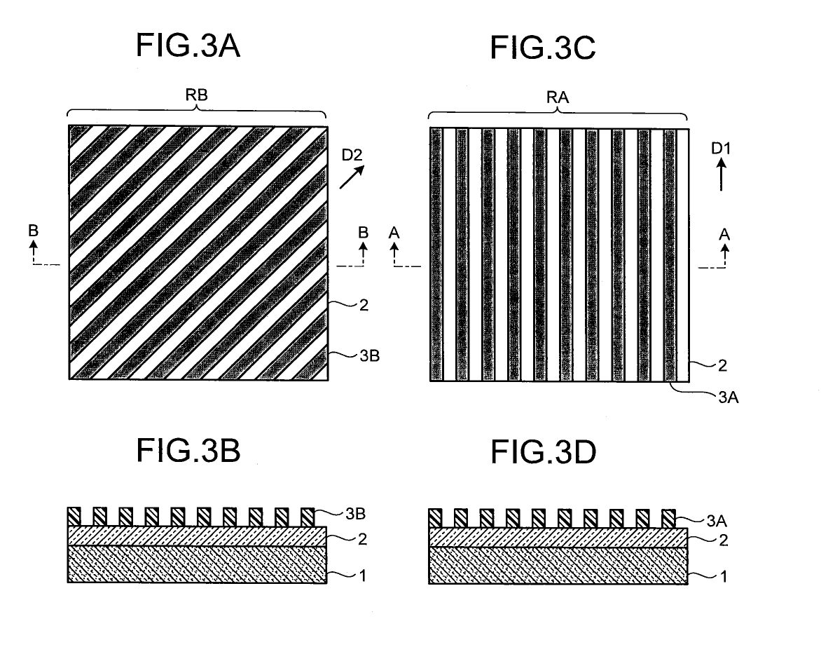

Next, as illustrated in FIGS. 3A to 3D, a resist film is formed on the hard mask material 2 in the effective region RA and the peripheral region RB by a method such as spin coating. Then, the resist film is exposed to light via the photomask M1 illustrated in FIG. 1A to form latent image patterns corresponding to the lines and spaces PA and PB on the resist film. Then, the resist film with the latent image patterns is developed to form the resist pattern 3A corresponding to the lines and spaces PA in the effective region RA, and form a resist pattern 3B corresponding to the lines and spaces PB in the peripheral region RB. At that time, the longitudinal side of the resist pattern 3A may be set along the first direction D1, and the longitudinal side of the resist pattern 3B may be set along the second direction D2.

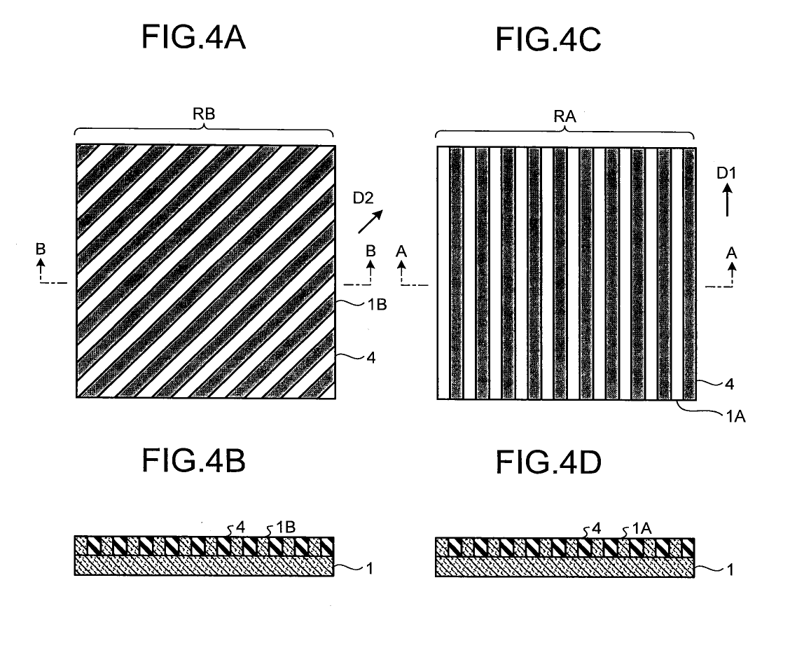

Next, as illustrated in FIGS. 4A to 4D, the hard mask material 2 is etched via the resist patterns 3A and 3B to transfer the resist patterns 3A and 3B to the hard mask material 2. Then, the semiconductor substrate 1 is etched via the hard mask material 2 to which the resist patterns 3A and 3B are transferred, thereby to form a process pattern 1A corresponding to the lines and spaces PA in the effective region RA, and form a process pattern 1B corresponding to the lines and spaces PB in the peripheral region RB. At that time, the longitudinal side of the process pattern 1A may be set along the first direction D1, and the longitudinal side of the process pattern 1B may be set along the second direction D2. The process pattern 1A in the effective region RA may be used as an active region of the NAND-type flash memory. Then, an insulating film is deposited on the process patterns 1A and 1B by a method such as CVD, and then the insulating film is thinned by a method such as CMP until the surface of the process patterns 1A and 1B is exposed to view, thereby to form an element separation film 4 in trenches between the process patterns 1A and 1B. The material for the element separation film 4 may be a silicon dioxide film or a silicon nitride film, for example.

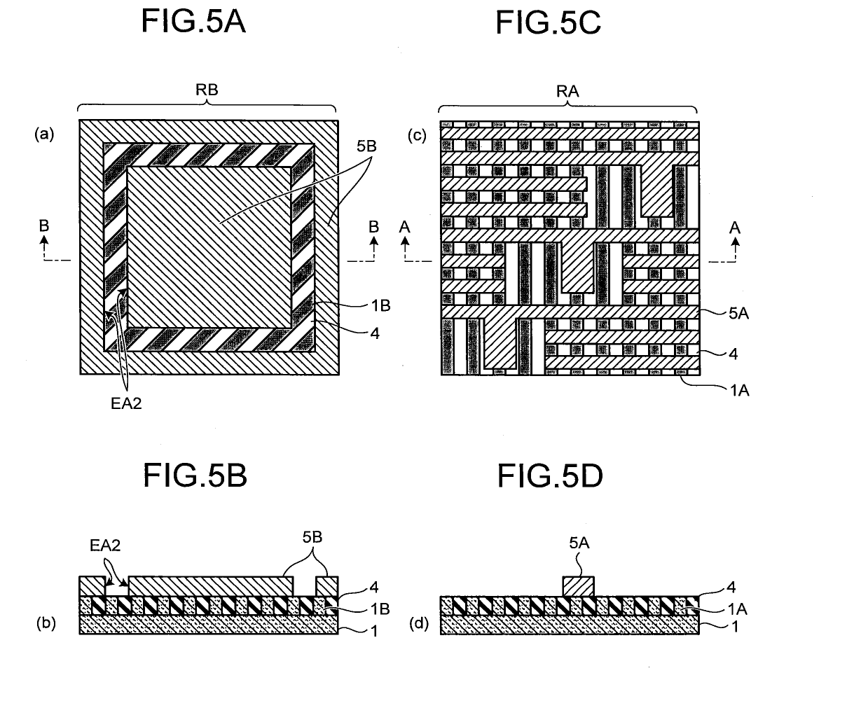

Next, as illustrated in FIGS. 5A to 5D, a wiring material and a resist film are sequentially formed on the foundation structure including the process patterns 1A and 1B and the element separation film 4. Then, the resist film is exposed to light via the photomask M2 illustrated in FIG. 1B, and then the resist film is developed to transfer the mask pattern on the photomask M2 to the resist film. Then, the wiring material is etched via the resist film to which the mask pattern is transferred, thereby to form a process pattern 5A corresponding to the mask pattern in the effective region MA2 in the effective region RA and form a process pattern 5B corresponding to the alignment marks KB2 and the overlapping gap measurement marks KA2 in the peripheral region RB. The material for the process patterns 5A and 5B may be polycrystalline silicon or metal such as Al, Cu, or W. In addition, the process pattern 5A in the effective region RA may be used as a gate line of the NAND-type flash memory. At that time, the mask pattern in the effective region MA2 on the photomask M2 may be formed by lines and spaces. The lines and spaces may be divided or connected to a land. The land may be used as a contact region for the gate line. Edges EA2 of the process pattern 5B may be set along the first direction D1.

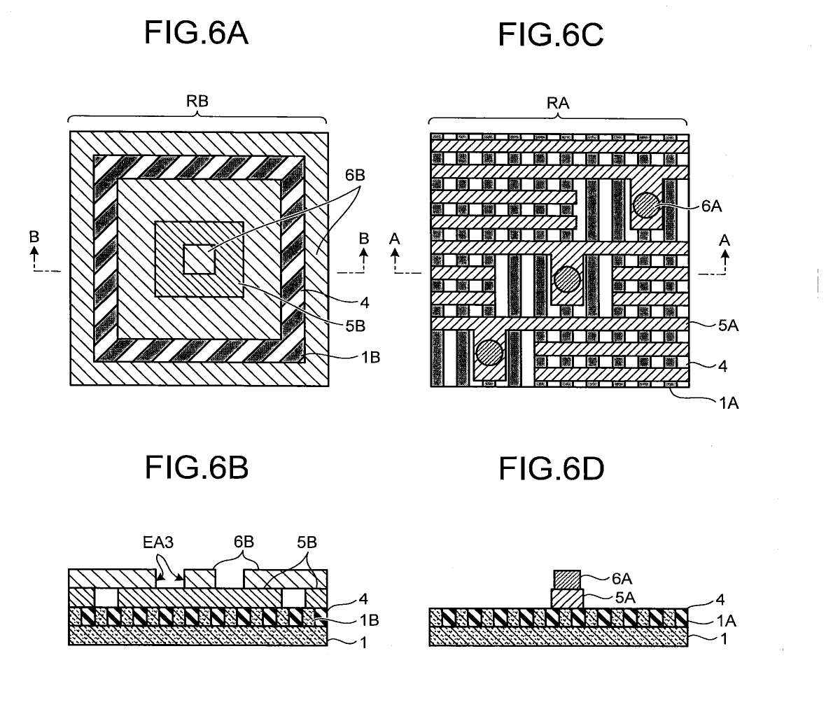

Next, as illustrated in FIGS. 6A to 6D, a contact material and a resist film are sequentially formed on the process patterns 5A and 5B. Then, the resist film is exposed to light via the photomask M3 illustrated in FIG. 1C, and then the resist film is developed to transfer the mask pattern on the photomask M3 to the resist film. Then, the contact material is etched via the resist film to which the mask patterns are transferred, thereby to form in the effective region RA a process pattern 6A corresponding to the mask pattern in the effective region MA3 and form in the peripheral region RB a process pattern 6B corresponding to the alignment marks KB3 and the overlapping gap measurement marks KA3. The material for the process patterns 6A and 6B may be metal such as Al, Cu, or W. Edges EA3 of the process pattern 6B may be set along the first direction D1.

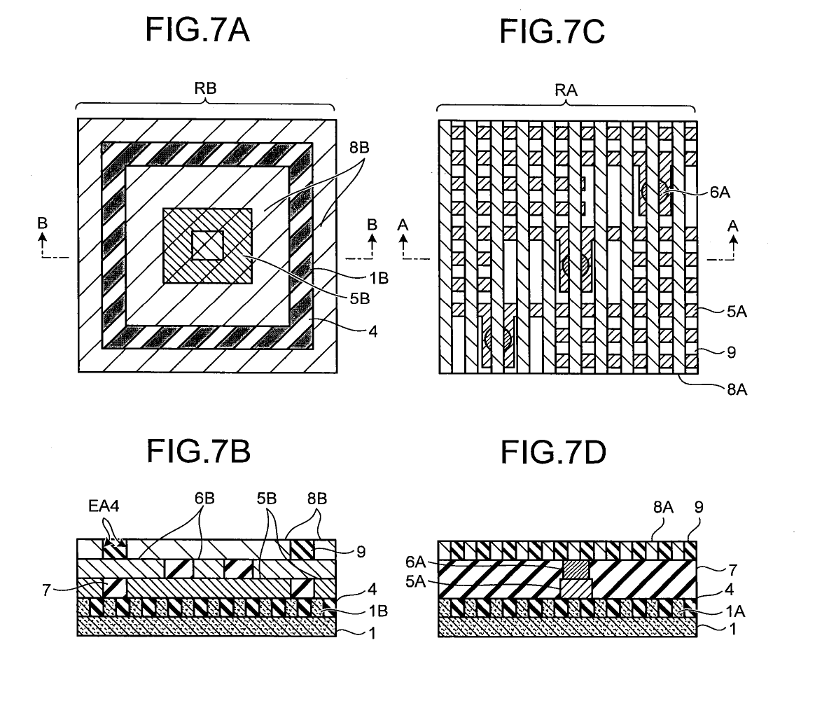

Next, as illustrated in FIGS. 7A to 7D, the process patterns 5A, 5B, 6A, and 6B are embedded into an inter-layer insulating film 7. Then, a wiring material and a resist film are sequentially formed on the process patterns 6A and 6B. Then, the resist film is exposed to light via the photomask M4 illustrated in FIG. 1D, and then the resist film is developed to transfer the mask pattern on the photomask M4 to the resist film. Then, the wiring material is etched via the resist film to which the mask pattern is transferred, thereby to form in the effective region RA a process pattern 8A corresponding to the mask pattern in the effective region MA4, and form in the peripheral region RB a process pattern 8B corresponding to the alignment marks KB4 and the overlapping gap measurement marks KA4. The material for the process patterns 8A and 8B may be metal such as Al, Cu, or W. In addition, the process pattern 8A in the effective region RA may be used as a bit line of the NAND-type flash memory. At that time, the mask pattern in the effective region MA4 on the photomask M4 may be formed by lines and spaces. Edges EA4 of the process pattern 8B may be set along the first direction D1.

By arranging the lines and spaces PA and PB in the effective region MA1 and the peripheral region MB1, respectively, on the photomask M1, it is possible to form the foundation structure including the process patterns 5B, 6B, and 8B by the process pattern 1B corresponding to the lines and spaces PB, and make the foundation structure including the process patterns 5B, 6B, and 8B equivalent to the process pattern 1A corresponding to the lines and spaces PA. Accordingly, in the case where process conditions are optimized for the process pattern 1A corresponding to the lines and spaces PA, process conditions can also be optimized for the foundation structure including the process patterns 5B, 6B, and 8B. This makes it possible to improve the dimension accuracy of the process patterns 5B, 6B, and 8B.

In addition, by setting differently the longitudinal sides of the lines and spaces PA and PB, it is possible to prevent that the edges EA2 to EA4 of the process patterns 5B, 6B, and 8B cannot be differentiated from the edges of the process pattern 1B of the foundation structure. This makes it possible to reduce errors in the alignment on exposure or the overlapping gap measurement after the exposure.

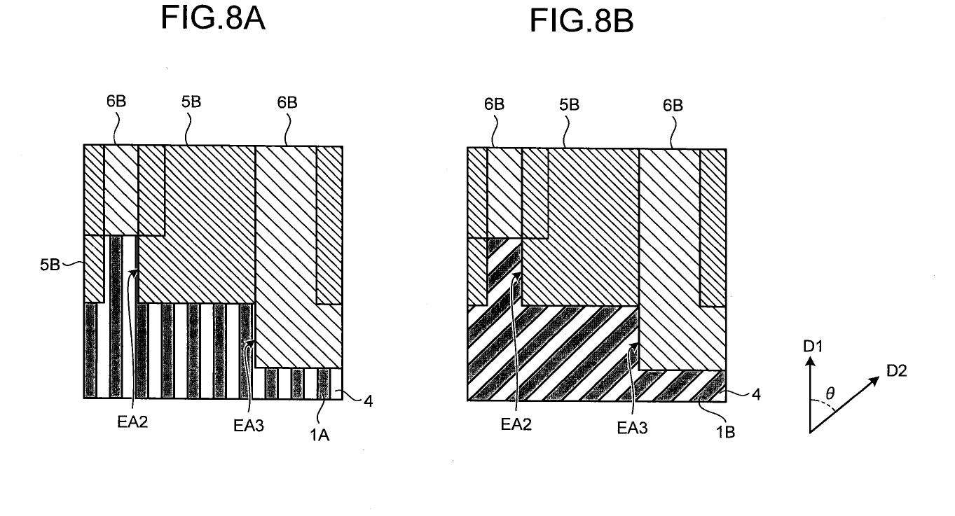

FIG. 8A is a plane view illustrating the observed state of overlapping gap measurement marks in the case where lines and spaces on the lower layer in the peripheral region are equally inclined in the peripheral region and the effective region, and FIG. 8B is a plane view illustrating the observed state of the overlapping gap measurement marks in the case where lines and spaces on the lower layer in the peripheral region are differently inclined in the peripheral region and the effective region.

Referring to FIG. 8A, it is assumed that the longitudinal side of the process pattern 1A formed by lines and spaces is set along the first direction D1, and the edges EA2 to EA3 of the process patterns 5B and 6B are set along the first direction D1. In this case, there is the possibility that it is difficult to differentiate the edges EA2 to EA3 of the process patterns 5B and 6B from edges of the process pattern 1A, which results in errors of alignment on exposure and overlapping gap measurement after the exposure.

In contrast to this, as illustrated in FIG. 8B, it is assumed that the longitudinal side of the process pattern 1B formed by lines and spaces is set along the second direction D2, and the edges EA2 to EA3 of the process patterns 5B and 6B are set along the first direction D1. In this case, it is easy to differentiate the edges EA2 to EA3 of the process patterns 5B and 6B from edges of the process pattern 1B, which makes it possible to reduce errors of alignment on exposure and overlapping gap measurement after the exposure.

### Third Embodiment

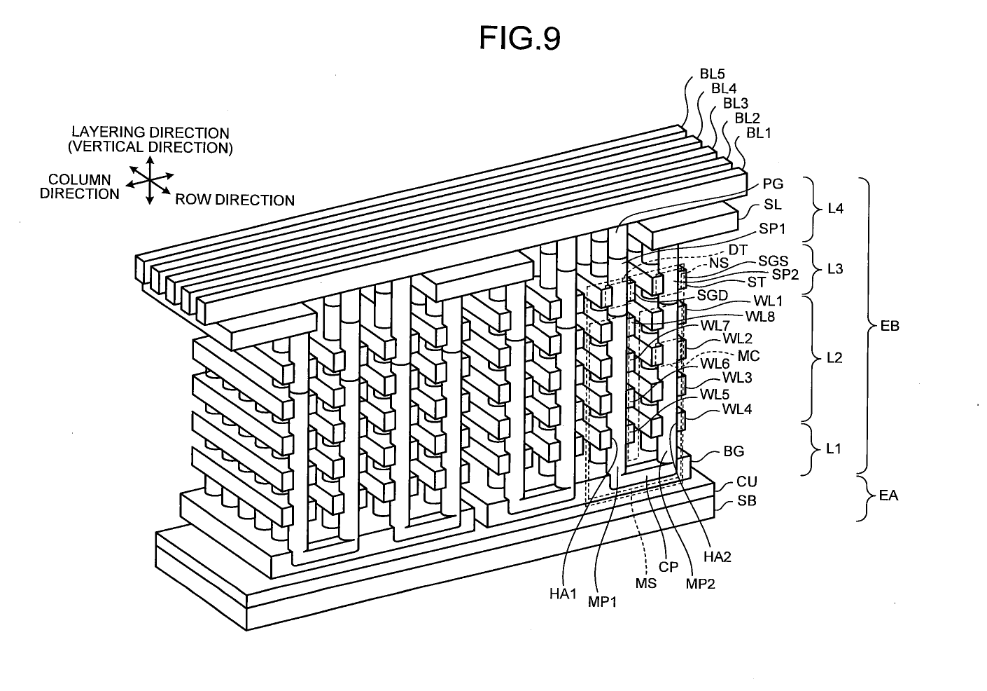

FIG. 9 is a schematic perspective view of a semiconductor device to which a photomask according to a third embodiment is applied. In the example of FIG. 9, a memory cell array of a three-dimensional NAND flash memory is taken as a semiconductor device.

Referring to FIG. 9, the memory cell array has a circuit region EA and a memory region EB. The circuit region EA is formed on a semiconductor substrate SB. The memory region EB is formed on the circuit region EA. The circuit region EA and the memory region EB may be formed in the effective region RA.

The memory cell array has a circuit layer CU, a back-gate transistor layer L1, a memory cell transistor layer L2, a select transistor layer L3, and a wiring layer L4, which are sequentially formed on the semiconductor substrate SB.

The back-gate transistor layer L1 functions as a back-gate transistor. The memory cell transistor layer L2 functions as cell transistors for memory cells MC. The select transistor layer L3 functions as select transistors ST and DT. The wiring layer L4 functions as a source line SL and bit lines BL1 to BL5.

The back-gate transistor layer L1 has a back-gate layer BG. The back-gate layer BG is extended two-dimensionally in a row direction and a column direction parallel to the semiconductor substrate SB. The back-gate layer BG is formed by polycrystalline silicon, for example.

The back-gate layer BG has a back-gate hole. The back-gate hole is formed by digging the back-gate layer BG. The back-gate hole is formed in the shape of an almost rectangle in which a longitudinal side thereof is arranged in the column direction as seen from top. A connection layer CP is formed in the back-gate hole.

The memory cell transistor layer L2 is formed on an upper layer of the back-gate transistor layer L1. The memory cell transistor layer L2 has word lines WL1 to WL8. The word lines WL1 to WL8 are layered with inter-layer insulating layers therebetween. The word lines WL1 to WL8 are formed in a striped pattern extending in the row direction with a predetermined pitch along the column direction. The word lines WL1 to WL8 are formed by polycrystalline silicon, for example.

The memory cell transistor layer L2 has memory holes HA1 and HA2. The memory holes HA1 and HA2 penetrate through the word lines WL1 to WL8. The memory holes HA1 and HA2 are formed so as to align with the vicinity of an end portion of the back-gate hole in the column direction. The cell transistors for the memory cells MC are connected together in series in a layering direction, and are connected to be folded back via the connection layer CP in the layering direction, thereby constituting a memory string MS.

The select transistor layer L3 has select gate lines SGS and SGD. The select gate lines SGS and SGD are formed in a stripe pattern extending in the row direction with a predetermined pitch along the column direction. A pair of select gate lines SGS and a pair of select gate lines SGD are alternately arranged in the column direction. The select gate lines SGS are formed on an upper layer of one columnar portion MP2, and the select gate lines SGD are formed on an upper layer of the other columnar portion MP1. The select gate lines SGS and SGD are formed by polycrystalline silicon.

The select transistor layer L3 has columnar portions SP1 and SP2. The columnar portions SP1 and SP2 penetrate through the select gate lines SGS and SGD, respectively. The columnar portions SP1 and SP2 are layered so as to align with the columnar portions MP1 and MP2, respectively. Select transistors ST and DT are connected in series to both ends of the memory string MS, thereby constituting an NAND string NS.

The wiring layer L4 is formed on an upper layer of the select transistor layer L3. The wiring layer L4 has a source line SL, a plug PG, and bit lines BL1 to BL5.

The source line SL is formed in the shape of a plate extending in the row direction. The source line SL is in contact with an upper surface of one pair of select gate lines SGS adjacent to each other in the column direction. The plug PG is in contact with an upper surface of the select gate line SGD and extended in a direction perpendicular to a surface of the semiconductor substrate SB. The bit lines BL1 to BL5 are formed in a stripe pattern extending in the column direction with a predetermined pitch in the row direction. The bit lines BL1 to BL5 are formed in contact with the upper surface of the plug PG. The source line SL, the plug PG, and the bit lines BL1 to BL5 are formed by a metal such as tungsten (W), for example. The patterns of the bit lines BL1 to BL5 and the word lines WL1 to WL8 may be formed by lines and spaces for each of the layers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a semiconductor device, comprising:
forming a first resist film on a first processing layer;
exposing the first resist film to light via a first photomask on which first lines and spaces are arranged in an effective region and second lines and spaces are arranged in a peripheral region;
developing the first resist film to form a first resist pattern corresponding to the first lines and spaces in the effective region on the first processing layer and form a second resist pattern corresponding to the second lines and spaces in the peripheral region on the first processing layer; and
processing the first processing layer via the first resist pattern and the second resist pattern to form a first process pattern in the effective region on the first processing layer and form a second process pattern in the peripheral region on the first processing layer, wherein
a longitudinal side of the first lines and spaces is set along a first direction and a longitudinal side of the second lines and spaces is set along a second direction different from the first direction.

2. The manufacturing method of a semiconductor device according to claim 1, comprising:
forming a second processing layer on the first processing layer on which the first process pattern and the second process pattern are formed;
forming a second resist film on the second processing layer;
exposing the second resist film to light via a second photomask on which a reference mark is arranged in a peripheral region;
developing the second resist film to form a third resist pattern corresponding to the reference mark in the peripheral region on the second processing layer; and
processing the second processing layer via the third resist pattern to form a third process pattern in the peripheral region on the second processing layer, wherein
an edge of the reference mark is set along a direction different from the second direction.

3. The manufacturing method of a semiconductor device according to claim 1, wherein the first lines and spaces and the second lines and spaces are equal to each other in pitch.

4. The manufacturing method of a semiconductor device according to claim 1, wherein an inclination angle of the second direction with respect to the first direction falls within a range of 20 to 80 degrees.

5. The manufacturing method of a semiconductor device according to claim 2, wherein the reference mark is an alignment mark.

6. The manufacturing method of a semiconductor device according to claim 2, wherein the reference mark is an overlapping gap measurement mark.

7. The manufacturing method of a semiconductor device according to claim 1, wherein a mask pattern to be a constitutional element of a device is formed in the effective region on the first photomask.

8. The manufacturing method of a semiconductor device according to claim 7, wherein the first process pattern is a gate line or an active region of an NAND flash memory.

9. The manufacturing method of a semiconductor device according to claim 7, wherein the first process pattern is a bit line of an NAND flash memory.

10. The manufacturing method of a semiconductor device according to claim 1, wherein a mask pattern not to be a constitutional element of a device is formed in the peripheral region on the first photomask.

11. The manufacturing method of a semiconductor device according to claim 2, wherein the edge of the reference mark is set along a direction equal to the first direction.

12. A photomask comprising:
first lines and spaces that have a longitudinal side set along a first direction and are arranged in an effective region; and
second lines and spaces that have a longitudinal side set along a second direction different from the first direction and are arranged in a peripheral region.

13. The photomask according to claim 12, wherein the first lines and spaces and the second lines and spaces are equal to each other in pitch.

14. The photomask according to claim 12, wherein an inclination angle of the second direction with respect to the first direction falls within a range of 20 to 80 degrees.

15. The photomask according to claim 12, comprising an alignment mark arranged in the peripheral region.

16. The photomask according to claim 12, comprising an overlapping gap measurement mark arranged in the peripheral region.

17. The photomask according to claim 12, wherein a mask pattern to be a constitutional element of a device is formed in the effective region.

18. The photomask according to claim 17, wherein the mask pattern corresponds to a gate line of an NAND flash memory.

19. The photomask according to claim 17, wherein the mask pattern corresponds to a bit line of an NAND flash memory.

20. The photomask according to claim 12, wherein a mask pattern not to be a constitutional element of a device is formed in the peripheral region.
